(19) United States
(12) Patent Application Publication
(10) Pub. No.: US 2023/0271568 A1
(43) Pub. Date: Aug. 31, 2023

(54) WIRE HARNESS UNIT

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(72) Inventors: Takeo MARUCHI, Yokkaichi-shi (JP); Masanori KUWAHARA, Yokkaichi-shi (JP); Yuichi KIMOTO, Yokkaichi-shi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 18/007,955

(22) PCT Filed: May 27, 2021
(86) PCT No.: PCT/JP2021/020242

§ 371 Date: Dec. 2, 2022

(30) Foreign Application Priority Data
Jun. 8, 2020 (JP) 2020-099406

(51) Int. Cl. B60R 16/02; H02G 3/03

(52) U.S. Cl. CPC B60R 16/0215; H02G 3/03

(57) ABSTRACT

A wire harness unit including: a conduction path that conducts electricity between in-vehicle devices; and a cooling tube that cools the conduction path, wherein: the conduction path has a hollow tubular conductor having conductivity, the cooling tube is more flexible than the tubular conductor and is separate from the tubular conductor, the cooling tube is connected to an end of the tubular conductor, and the tubular conductor and the cooling tube are configured to circulate a cooling medium therethrough.

### BACKGROUND

The present disclosure relates to a wire harness unit.

Conventionally, wire harnesses that are installed in vehicles such as hybrid vehicles and electric vehicles electrically connect a plurality of electrical devices. Also, with electric vehicles, a wire harness connects the vehicle to a ground facility, and the ground facility charges a power storage device installed in the vehicle. The amount of heat generated by the wire harness increases due to an increase in the voltage that is supplied by the wire harness. Configurations for cooling wire harnesses have thus been proposed.

For example, JP 2019-115253A discloses a wire harness that includes a coated wire, an inner tube that covers the coated wire and an outer tube that covers the inner tube with a predetermined interval therebetween, and in which a circulation channel for a cooling medium is formed between the inner tube and the outer tube. The circulation channel is formed by the inner and outer tubes that are separate from the coated wire, and the coated wire is disposed radially on the inner side of the circulation channel.

### SUMMARY

Incidentally, with the wire harness of JP 2019-115253A, the circulation channel (channel through which the cooling medium circulates) is disposed on the outer side of the coated wire, and thus the cooling medium is at a distance from the central portion of the coated wire which is the heat source, leaving room for improvement in terms of cooling efficiency of the coated wire.

An exemplary aspect of the disclosure provides a wire harness unit that enables cooling efficiency to be improved.

A wire harness unit according to one mode of the present disclosure includes a conduction path that conducts electricity between in-vehicle devices, and a cooling tube that cools the conduction path, the conduction path having a hollow tubular conductor having conductivity, the cooling tube is configured to circulate a cooling medium therethrough and is separate from the tubular conductor, the tubular conductor being superior in rigidity to the cooling tube, and the cooling tube passing through the tubular conductor.

With a wire harness unit which is one mode of the present disclosure, cooling efficiency can be improved.

### BRIEF DESCRIPTION OF THE DRAWINGS

FIG. 1 is a schematic diagram showing a vehicle in which a wire harness unit in one embodiment is routed.

FIG. 2 is a schematic diagram of the wire harness unit.

FIG. 3 is a partial cross-sectional view showing an outline of the wire harness unit.

FIG. 4 is a cross-sectional view of the wire harness unit.

FIG. 5 is an illustrative diagram showing the connection between a tubular conductor, flexible conductors and terminals.

FIG. 6 is a partial cross-sectional view showing an outline of the wire harness unit of an example modification.

### DETAILED DESCRIPTION OF EMBODIMENTS

### Description of Embodiments of Disclosure

Initially, embodiments of the present disclosure will be enumerated and described.
[1] A wire harness unit of the present disclosure includes a conduction path that conducts electricity between in-vehicle devices, and a cooling part that cools the conduction path, the conduction path having a hollow tubular conductor having conductivity, the cooling part having a cooling tube that is more flexible than the tubular conductor and is separate from the tubular conductor, the cooling tube being connected to an end portion of the tubular conductor, and the tubular conductor and the cooling tube being configured to circulate a cooling medium therethrough.

According to this configuration, by means of the cooling tube connected to either end of the tubular conductor, the cooling medium circulates through the tubular conductor. The tubular conductor is cooled through heat exchange with the cooling medium that circulates by means of the cooling tube. The tubular conductor can thus be cooled from the inner side, and cooling efficiency can be improved.
[2] Preferably, the wire harness unit has a protective layer covering an inner peripheral surface of the tubular conductor.

According to this configuration, the cooling medium that is supplied inside the tubular conductor can be prevented from coming into direct contact with the inner peripheral surface of the tubular conductor by the protective layer.
[3] Preferably, the conduction path has a flexible conductor and a terminal, the flexible conductor has a first end portion electrically connected to the tubular conductor and a second end portion electrically connected to the terminal, and the flexible conductor is more flexible than the tubular conductor.

According to this configuration, due to the flexible conductor being connected to the end portion of the tubular conductor, dimensional tolerance of the conduction path can be taken up. Furthermore, such a configuration also acts as a countermeasure against shaking that occurs when the vehicle is travelling.
[4] Preferably, the tubular conductor is longer than the flexible conductor.

According to this configuration, the section where heat exchange occurs between the cooling medium that is supplied inside the tubular conductor and the tubular conductor is lengthened, thus enabling the tubular conductor to be further cooled.
[5] Preferably, the wire harness unit includes an electromagnetic shielding member covering the tubular conductor and at least part of the cooling tube, and the electromagnetic shielding member is a braided member formed by braiding metal wire strands, and the cooling tube passes through the braided member.

According to this configuration, shieldability for suppressing emission of electromagnetic noise from the conduction path and assembly workability of the cooling part can both be achieved.
[6] Preferably, the wire harness unit includes an exterior member covering the conduction path and at least part of the cooling tube, the exterior member has a tubular exterior member and a grommet connected to an end portion of the tubular exterior member, and the cooling tube passes through the grommet.

According to this configuration, the cooling tube is led outside through a grommet, thus enabling deterioration in the water sealing performance of the wire harness unit to be suppressed.

### Detailed Description of Embodiments of Disclosure

Specific examples of a wire harness unit of the present disclosure will be described below with reference to the drawings. In the individual diagrams, parts of the configuration may be shown in an exaggerated or simplified manner, for convenience of description. Also, the dimensional ratios of various portions may differ between the diagrams. Herein, “parallel” and “orthogonal” include not only strictly parallel and orthogonal but also generally parallel and orthogonal within a range that achieves the operation and effects of the present embodiment. Note that the present disclosure is not limited to these illustrative examples and is defined by the claims, and all changes that come within the meaning and range of equivalency of the claims are intended to be embraced therein.

### Schematic Configuration of Wire Harness Unit 10

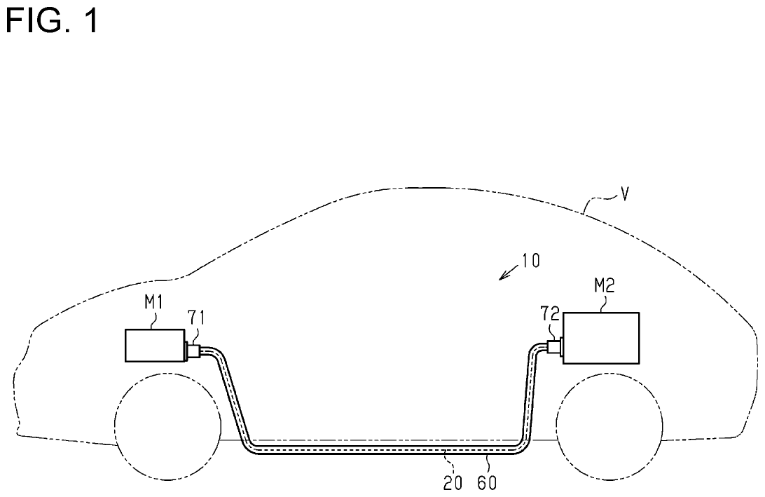

A wire harness unit 10 shown in FIG. 1 electrically connects two in-vehicle devices installed in a vehicle V. The vehicle V is, for example, a hybrid vehicle or an electric vehicle. The wire harness unit 10 has a conduction path 20 that electrically connects an in-vehicle device M1 and an in-vehicle device M2, and an exterior member 60 that covers the conduction path 20. The conduction path 20 is, for example, routed from the in-vehicle device M1 to the in-vehicle device M2 in a manner whereby part thereof in the length direction passes under the floor of the vehicle V. As examples of the in-vehicle device M1 and the in-vehicle device M2, the in-vehicle device M1 is an inverter installed toward the front of the vehicle V, and the in-vehicle device M2 is a high voltage battery installed more rearward in the vehicle V than the in-vehicle device M1. The in-vehicle device M1 serving as an inverter is, for example, connected to a motor (not shown) for driving wheels that serves as a power source for vehicle travel. The inverter generates AC power from DC power of the high voltage battery and supplies the AC power to the motor. The in-vehicle device M2 serving as a high voltage battery is, for example, a battery capable of supplying a voltage of 100 volts or more. Specifically, the conduction path 20 of the present embodiment constitutes a high voltage circuit that enables transmission of a high voltage between the high voltage battery and the inverter.

### Schematic Configuration of Wire Harness Unit 10

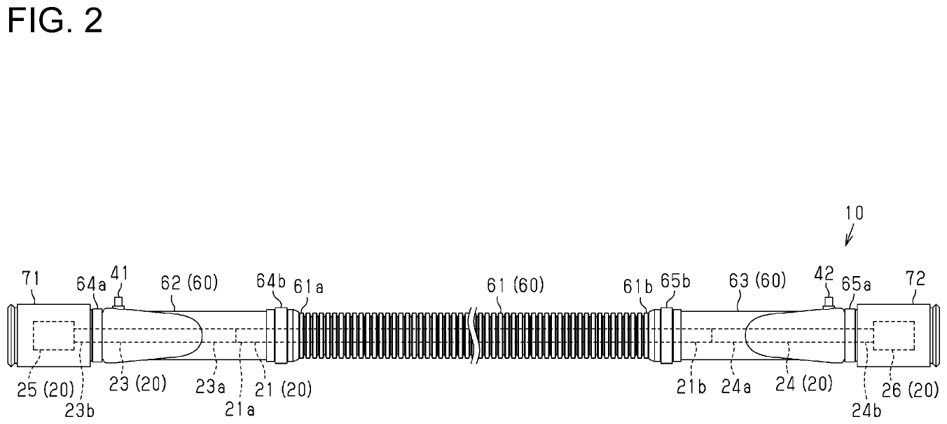

As shown in FIGS. 2, 3 and 4, the wire harness unit 10 has the conduction path 20, cooling tubes 41 and 42, an electromagnetic shielding member 50 (electromagnetic shield), the exterior member 60 (exterior cover), and connectors 71 and 72.

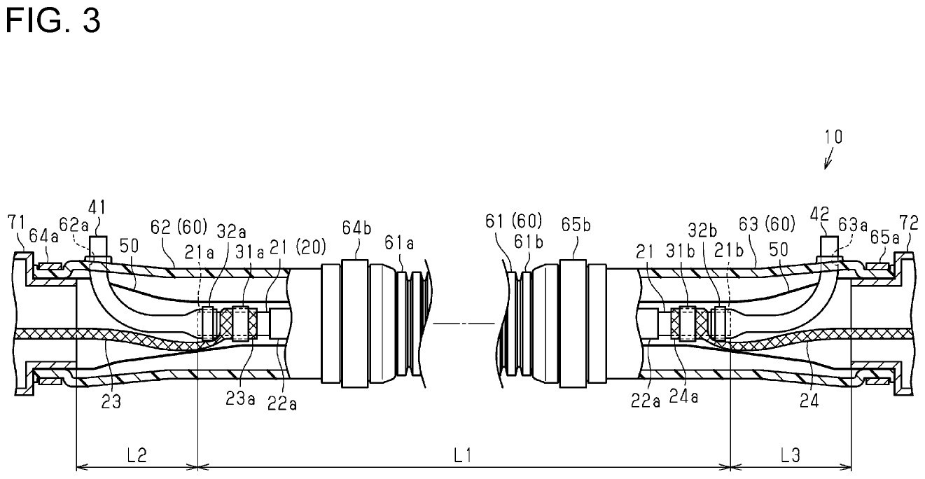

As shown in FIGS. 3, 4 and 5, the conduction path 20 has a tubular conductor 21, an insulating coating 22a, a protective layer 22b, flexible conductors 23 and 24, and terminals 25 and 26.

The tubular conductor 21 has conductivity and an internally hollow structure. The tubular conductor 21 is made of a metal, for example, and has high shape retention. That is, the tubular conductor 21 is capable of retaining its shape. The material of the tubular conductor 21 is a copper-based or aluminum-based metal material, for example. The tubular conductor 21 is formed into a shape that corresponds to the routing path of the wire harness unit shown in FIG. 1. The tubular conductor 21 is subjected to a bending process by a pipe bender (pipe bending machine).

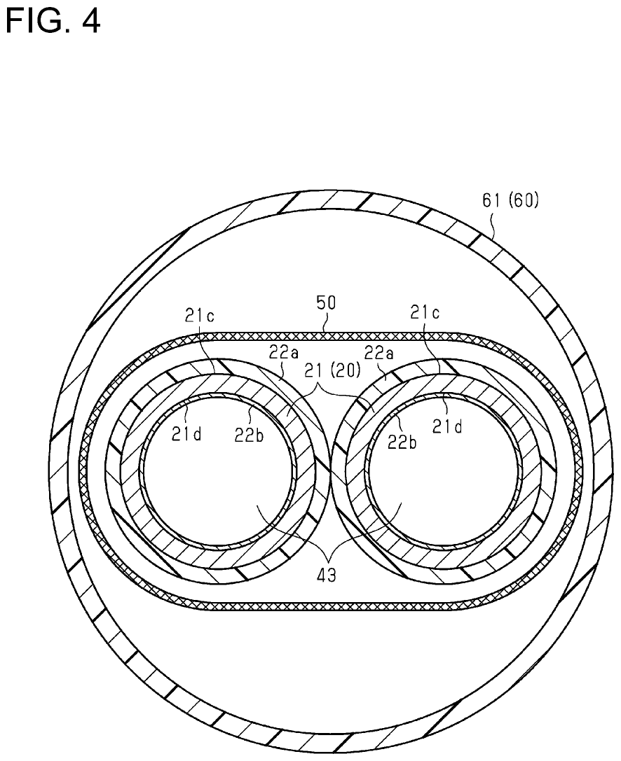

FIG. 4 shows a cross-section in which the wire harness unit 10 is cut by a plane orthogonal to the length direction of the wire harness unit 10. In FIG. 4, the length direction of the tubular conductor 21 is the depth direction as it appears in FIG. 4. The cross-sectional shape (i.e., transverse sectional shape) obtained by cutting the tubular conductor 21 by a plane perpendicular to the length direction of the tubular conductor 21, that is, the axial direction of the tubular conductor 21 which is the direction in which the tubular conductor 21 extends, is annular, for example. Note that the cross-sectional shape of the tubular conductor 21 can be any shape. Also, in the cross-sectional shape of the tubular conductor 21, the outer peripheral shape and the inner peripheral shape may differ from each other. Also, the cross-sectional shape may differ in the length direction of the tubular conductor 21.

The insulating coating 22a covers an outer peripheral surface 21c of the tubular conductor 21 around the entire circumference in the circumferential direction. The insulating coating 22a is constituted by an insulating material such as a synthetic resin, for example. As the material of the insulating coating 22a, a silicone resin or a synthetic resin whose main component is a polyolefin resin such as crosslinked polyethylene or crosslinked polypropylene can be used, for example. As the material of the insulating coating 22a, one material can be used on its own, or two or more materials can be used in combination as appropriate. The insulating coating 22a can be formed by extrusion molding (extrusion coating) performed on the tubular conductor 21, for example.

The protective layer 22b covers an inner peripheral surface 21d of the tubular conductor 21 around the entire circumference in the circumferential direction. The protective layer 22b is, for example, a coating such as a rigid resin, rubber or enamel coating. The protective layer 22b prevents a cooling medium 43 that is supplied inside the tubular conductor 21 from coming into direct contact with the inner peripheral surface 21d of the tubular conductor 21.

As shown in FIG. 3, the tubular conductor 21 has a first end portion 21a and a second end portion 21b that are the two ends of the tubular conductor 21 in the length direction. The first end portion 21a and the second end portion 21b are exposed from the insulating coating 22a.

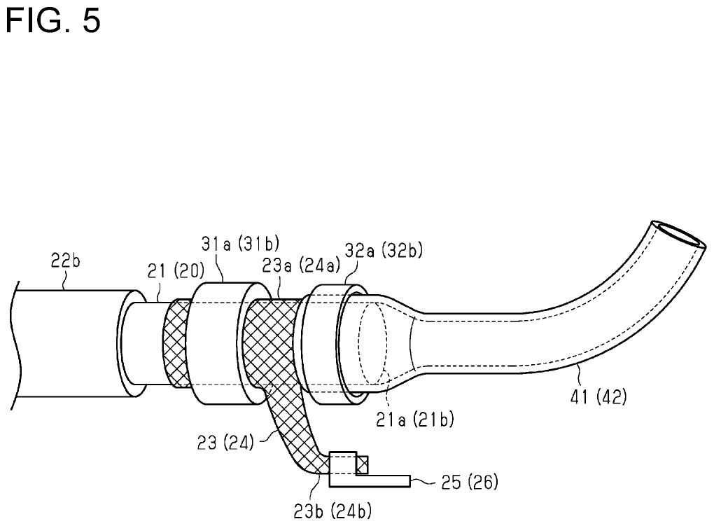

As shown in FIGS. 3 and 5, the flexible conductors 23 and 24 are each connected at one end to the tubular conductor 21, and the terminals 25 and 26 shown in FIG. 2 are respectively connected to the other ends of the flexible conductors 23 and 24. To elaborate, the flexible conductor 23 has a first end portion 23a that is electrically connected to the tubular conductor 21, and a second end portion 23b that is electrically connected to the terminal 25 shown in FIGS. 2 and 5. The flexible conductor 24 has a first end portion 24a that is electrically connected to the tubular conductor 21, and a second end portion 24b that is electrically connected to the terminal 26 shown in FIG. 2.

The flexible conductors 23 and 24 are conductors that are superior in flexibility to the tubular conductor 21. The flexible conductors 23 and 24 of the present embodiment are formed in a tubular shape. The flexible conductors 23 and 24 are, for example, braided wires formed by braiding conductive wire strands into a tubular shape. The material of the wire strands is, for example, a copper-based or aluminum-based metal material.

As shown in FIG. 3, the tubular conductor 21 is disposed on the inner side of the first end portion 23a of the flexible conductor 23 formed in a tubular shape, and the first end portion 21a of the tubular conductor 21 passes through the flexible conductor 23 and is arranged outside the flexible conductor 23. A fastening band 31a is mounted on the outer peripheral side of the flexible conductor 23. The flexible conductor 23 is crimped to the outer peripheral surface of the tubular conductor 21 by the fastening band 31a. By means of the fastening band 31a, the first end portion 23a of the flexible conductor 23 is electrically connected to the outer peripheral surface of the tubular conductor 21. Note that the tubular conductor 21 and the flexible conductor 23 may be connected by welding such as ultrasonic welding, for example.

The tubular conductor 21 is disposed on the inner side of the first end portion 24a of the flexible conductor 24 formed in a tubular shape, and the second end portion 21b of the tubular conductor 21 passes through the flexible conductor 24 and is arranged outside the flexible conductor 24. A fastening band 31b is mounted on the outer side of the flexible conductor 24. The flexible conductor 24 is crimped to the outer peripheral surface of the tubular conductor 21 by the fastening band 31b. By means of the fastening band 31b, the first end portion 24a of the flexible conductor 24 is electrically connected to the outer peripheral surface of the tubular conductor 21. Note that the flexible conductor 24 and the tubular conductor 21 may be connected by welding such as ultrasonic welding, for example.

FIG. 5 is an illustrative diagram showing the connection between the tubular conductor, the flexible conductors and the terminals. Note that, in FIG. 5, the members of the conduction path 20 shown on the left side of FIGS. 2 and 3 are indicated by reference numerals without parentheses, and the members shown on the right side of FIGS. 2 and 3 are indicated by reference numerals in parentheses.

The terminal 25 is held in the connector 71 shown in FIGS. 1 and 2, and is connected to the in-vehicle device M1. The terminal 25 is connected to the second end portion 23b of the flexible conductor 23. For example, the terminal 25 has a pair of crimping pieces, and is crimped to the second end portion 23b of the flexible conductor 23 by these crimping pieces. The terminal 26 is held in the connector 72 shown in FIGS. 1 and 2, and is connected to the in-vehicle device M2. The terminal 26 is connected to the second end portion 24b of the flexible conductor 24. For example, the terminal 26 has a pair of crimping pieces, and is crimped to the second end portion 24b of the flexible conductor 24 by these crimping pieces.

As shown in FIGS. 3 and 4, the cooling tubes 41 and 42 are respectively connected to either end of the tubular conductor 21. The cooling tubes 41 and 42 are formed in a hollow shape. The cooling tubes 41 and 42 are superior in flexibility to the tubular conductor 21. In other words, the tubular conductor 21 is superior in rigidity to the cooling tubes 41 and 42. The material of the cooling tubes 41 and 42 is a resin material having flexibility, such as PP (polypropylene), PVC (polyvinyl chloride) or crosslinked PE (polyethylene).

To elaborate, the cooling tube 41 is connected to the first end portion 21a of the tubular conductor 21. As shown in FIG. 3, the first end portion 21a of the tubular conductor 21 is arranged on the inner side of the end portion of the cooling tube 41 formed in a tubular shape. A fastening band 32a is mounted on the outer peripheral side of the cooling tube 41. The cooling tube 41 is crimped to the outer peripheral surface of the tubular conductor 21 by the fastening band 32a.

In the present embodiment, the cooling tube 41 is crimped further at the end portion of the tubular conductor 21 than the flexible conductor 23 described above. That is, the fastening band 32a that crimps the cooling tube 41 to the tubular conductor 21 is disposed further on the end portion side of the tubular conductor 21 than the fastening band 31a that crimps the flexible conductor 23 to the tubular conductor 21. Also, the flexible conductor 23 covers the cooling tube 41 and the fastening band 32a that crimps the cooling tube 41 to the tubular conductor 21.

Similarly, the cooling tube 42 is connected to the second end portion 21b of the tubular conductor 21. As shown in FIG. 3, the second end portion 21b of the tubular conductor 21 is arranged on the inner side of the end portion of the cooling tube 42 formed in a tubular shape. A fastening band 32b is mounted on the outer peripheral side of the cooling tube 42. The cooling tube 42 is crimped to the outer peripheral surface of the tubular conductor 21 by the fastening band 32b.

In the present embodiment, the cooling tube 42 is crimped further at the end portion of the tubular conductor 21 than the flexible conductor 24 described above. That is, the fastening band 32b that crimps the cooling tube 42 to the tubular conductor 21 is disposed further on the end portion side of the tubular conductor 21 than the fastening band 31b that crimps the flexible conductor 24 to the tubular conductor 21. Also, the flexible conductor 24 covers the cooling tube 42 and the fastening band 32b that crimps the cooling tube 42 to the tubular conductor 21.

The cooling tubes 41 and 42 function as a channel for supplying the cooling medium 43 to and a channel for discharging the cooling medium 43 from the tubular conductor 21.

The cooling medium 43 is supplied inside the tubular conductor 21 via the cooling tube 41, for example. The cooling medium 43 is, for example, any of various types of fluids such as a liquid like water or antifreeze, a gas or a gas-liquid two-phase flow consisting of a mixture of a gas and a liquid. The cooling medium 43 is supplied by a pump not shown. The cooling medium 43 that is supplied inside the tubular conductor 21 is discharged via the cooling tube 42, for example. In this way, the cooling tubes 41 and 42 constitute part of a circulation channel that circulates the cooling medium 43. The circulation channel includes, for example, the pump described above and a heat dissipation part. The pump pumps the cooling medium into the tubular conductor 21 from the cooling tube 41. The cooling medium 43 exchanges heat with the tubular conductor 21. The cooling medium 43 whose temperature has risen due to the heat exchange is sent from the tubular conductor 21 to the heat dissipation part by the cooling tube 42. The heat dissipation part dissipates the heat of the cooling medium 43 whose temperature has risen due to the heat exchange externally and cools the cooling medium 43. The cooled cooling medium 43 is again pumped by the pump to the tubular conductor 21 via the cooling tube 41. The cooling tubes 41 and 42 constitute a cooling part that cools the tubular conductor 21 with the cooling medium 43 that circulates in this way.

As shown in FIGS. 3 and 4, the electromagnetic shielding member 50 covers two conduction paths 20. The electromagnetic shielding member 50 is a braided member formed by braiding metal wire strands into a tubular shape. The electromagnetic shielding member 50 has shieldability. Also, the electromagnetic shielding member 50 has flexibility. As shown in FIG. 3, one end of the electromagnetic shielding member 50 is connected to the connector 71, and the other end of the electromagnetic shielding member 50 is connected to the connector 72. Accordingly, the electromagnetic shielding member 50 covers the entire length of the conduction paths 20 that transmit a high voltage. External emission of electromagnetic noise that is generated from the conduction paths 20 is thereby suppressed.

The exterior member 60 covers the conduction paths 20. In each conduction path 20, the cooling tubes 41 and 42 described above are respectively connected to either end portion of the tubular conductor 21. Accordingly, the exterior member 60 covers the conduction paths 20 and at least part of the cooling tubes 41 and 42.

The exterior member 60 has a tubular exterior member 61 (tubular exterior) and grommets 62 and 63 respectively connected to a first end portion 61a and a second end portion 61b of the tubular exterior member 61.

The tubular exterior member 61 is, for example, provided so as to cover part of the outer periphery of the tubular conductor 21 in the length direction. The tubular exterior member 61 has, for example, a tubular shape in which both ends in the length direction of the tubular conductor 21 are open. The tubular exterior member 61 is, for example, provided so as to enclose the outer periphery of the plurality of tubular conductors 21 around the entire circumference in the circumferential direction. The tubular exterior member 61 of the present embodiment is formed in a cylindrical shape. The tubular exterior member 61 has, for example, a bellows structure in which an annular raised portion and an annular recessed portion are alternately connected continuously in the axial direction (length direction) in which the center axis of the tubular exterior member 61 extends. As the material of the tubular exterior member 61, a resin material having conductivity or a resin material not having conductivity can be used, for example. As the resin material, a synthetic resin such as polyolefin, polyamide, polyester or ABS resin can be used, for example. The tubular exterior member 61 of the present embodiment is a corrugated tube made of synthetic resin.

The grommet 62 is formed in a generally tubular shape. The grommet 62 is made of rubber, for example. The grommet 62 is formed so as to bridge between the connector 71 and the tubular exterior member 61. The grommet 62 is fastened and fixed by a fastening band 64a so as to be in intimate contact with the outer surface of the connector 71. Also, the grommet 62 is fastened and fixed by a fastening band 64b so as to be in intimate contact with the outer side of the first end portion 61a of the tubular exterior member 61. A through hole 62a that passes through the grommet 62 is formed in the grommet 62. The through hole 62a communicates between the inside and outside of the grommet 62.

In the present embodiment, two through holes 62a are formed in the grommet 62, and the cooling tubes 41 are inserted through the through holes 62a. The through holes 62a are formed so as to be in intimate contact with the outer peripheral surface of the cooling tubes 41 that are inserted therethrough. As shown in FIG. 3, the cooling tubes 41 pass through the flexible conductors 23 and the electromagnetic shielding member 50, and are led outside the grommet 62 via the through holes 62a in the grommet 62.

The grommet 63 is formed in a generally tubular shape. The grommet 63 is made of rubber, for example. The grommet 63 is formed so as to bridge between the connector 72 and the tubular exterior member 61. The grommet 63 is fastened and fixed by a fastening band 65a so as to be intimate contact with the outer surface of the connector 72. Also, the grommet 63 is fastened and fixed by a fastening band 65b so as to be in intimate contact with the outer side of the second end portion 61b of the tubular exterior member 61. A through hole 63a that passes through the grommet 63 is formed in the grommet 63. The through hole 63a communicates between the inside and outside of the grommet 63.

In the present embodiment, two through holes 63a are formed in the grommet 63, and the cooling tubes 42 are inserted through the through holes 63a. The through holes 63a are formed so as to be in intimate contact with the outer peripheral surface of the cooling tubes 42 that are inserted therethrough. As shown in FIG. 3, the cooling tubes 42 pass through the flexible conductors 24 and the electromagnetic shielding member 50, and are led outside the grommet 63 via the through holes 63a in the grommet 63.

### Operation

Next, the operation of the wire harness unit 10 of the present embodiment will be described.

The wire harness unit 10 includes the conduction path 20 that conducts electricity between the in-vehicle devices M1 and M2, and the cooling tubes 41 and 42 constituting the cooling part that cools the conduction path 20. The conduction path 20 has the hollow tubular conductor 21 having conductivity. The cooling tubes 41 and 42 are superior in flexibility to the tubular conductor 21 and are separate from the tubular conductor 21. The cooling tubes 41 and 42 are respectively connected to either end portion of the tubular conductor 21. The tubular conductor 21 and the cooling tubes 41 and 42 are configured to circulate the cooling medium 43 therethrough.

By means of the cooling tubes 41 and 42 respectively connected to either end portion of the tubular conductor 21, the cooling medium 43 circulates through the tubular conductor 21. The tubular conductor 21 is cooled through heat exchange with the cooling medium 43 that is circulated by the cooling tubes 41 and 42. In this way, the tubular conductor 21 can be cooled from the inner side.

The tubular conductor 21 has a longer outer peripheral length, compared with a single core wire having a solid structure or a twisted wire formed by twisting together a plurality of metal wire strands having the same cross-sectional area. That is, the tubular conductor 21 has a larger area on the outer peripheral side, compared with a single core wire or a twisted wire. Accordingly, heat can be dissipated externally from a larger area, thus enabling heat dissipation to be improved.

The wire harness unit 10 has the protective layer 22b that covers the inner peripheral surface 21d of the tubular conductor 21 around the entire circumference in the circumferential direction. By means of the protective layer 22b, the cooling medium 43 that is supplied inside the tubular conductor 21 can be prevented from coming into direct contact with the inner peripheral surface 21d of the tubular conductor 21.

The conduction path 20 has the flexible conductors 23 and 24 connected to the tubular conductor 21. The flexible conductors 23 and 24 are superior in flexibility to the tubular conductor 21. Accordingly, dimensional tolerance of the conduction path 20 can be taken up. Also, when the vehicle V vibrates, positional shift between the components connected to either side of the flexible conductors 23 and 24 caused by this vibration can be absorbed. In the present embodiment, positional shift between the tubular conductor 21 and the connectors 71 and 72, that is, between the tubular conductor 21 and the in-vehicle devices M1 and M2, can be absorbed. Accordingly, the load that is applied to the connectors 71 and 72 and the terminals 25 and 26 can be reduced.

Also, as shown in FIG. 3, a length L1 of the tubular conductor 21 is longer than lengths L2 and L3 of the flexible conductors 23 and 24. The lengths L2 and L3 of the flexible conductors 23 and 24 are lengths indicating the range over which the conduction path 20 is bendable due to the flexibility of the flexible conductors 23 and 24. In the present embodiment, the lengths L2 and L3 are respectively the distances between the tubular conductor 21 and the connectors 71 and 72. Accordingly, the section where the cooling medium 43 that is circulated by the cooling tubes 41 and 42 contacts the tubular conductor 21 is long, that is, the section heat where exchange occurs between the cooling medium 43 and the tubular conductor 21 can be lengthened, thus enabling the conduction path 20 to be further cooled. Note that the lengths L2 and L3 of the flexible conductors 23 and 24 may be equal to each other or may be different from each other.

The flexible conductors 23 and 24 of the present embodiment are braided members formed by braiding metal wire strands into a tubular shape. The cooling tubes 41 and 42 can thus be respectively led out through the flexible conductors 23 and 24, partway along the flexible conductors 23 and 24. The cooling tubes 41 and 42 can thereby be easily led outside the wire harness unit 10, and the constituent members for circulating the cooling medium 43 can be easily connected to the tubular conductor 21.

The electromagnetic shielding member 50 covers two conduction paths 20. The electromagnetic shielding member 50 is a braided member formed by braiding metal wire strands into a tubular shape. External emission of electromagnetic noise that is generated from the conduction paths 20 can thus be suppressed. Also, the cooling tubes 41 and 42 can thus be led out through the electromagnetic shielding member 50, partway along the electromagnetic shielding member 50. The cooling tubes 41 and 42 can thereby be easily led outside the wire harness unit 10, and the constituent members for circulating the cooling medium 43 can be easily connected to the tubular conductors 21.

The wire harness unit 10 includes the exterior member 60 that covers the conduction paths 20 and at least part of the cooling tubes 41 and 42. The exterior member 60 has the tubular exterior member 61 and the grommets 62 and 63 respectively connected to the first end portion 61a and the second end portion 61b of the tubular exterior member 61. The cooling tubes 41 and 42 respectively pass through the grommets 62 and 63. In this way, the cooling tubes 41 and 42 respectively pass through the grommets 62 and 63 and are led outside the wire harness unit 10, thus enabling deterioration in the water sealing performance of the wire harness unit 10 to be suppressed.

As described above, according to the present embodiment, the following effects are achieved.
(1) The wire harness unit 10 includes the conduction path 20 that conducts electricity between the in-vehicle devices M1 and M2, and the cooling tubes 41 and 42 constituting the cooling part that cools the conduction path 20. The conduction path 20 has a hollow tubular conductor 21 having conductivity. The cooling tubes 41 and 42 are superior in flexibility to the tubular conductor 21 and are separate from the tubular conductor 21. The cooling tubes 41 and 42 are respectively connected to either end portion of the tubular conductor 21. The tubular conductor 21 and the cooling tubes 41 and 42 are configured to circulate the cooling medium 43 therethrough.

By means of the cooling tubes 41 and 42 respectively connected to either end portion of the tubular conductor 21, the cooling medium 43 circulates through the tubular conductor 21. The tubular conductor 21 is cooled through heat exchange with the cooling medium 43 that is circulated by the cooling tubes 41 and 42. In this way, the tubular conductor 21 can be cooled from the inner side.
(2) The wire harness unit 10 has the protective layer 22b that covers the inner peripheral surface 21d of the tubular conductor 21 around the entire circumference in the circumferential direction. By means of the protective layer 22b, the cooling medium 43 that is supplied inside the tubular conductor 21 can be prevented from coming into direct contact with the inner peripheral surface 21d of the tubular conductor 21.
(3) The tubular conductor 21 has a longer outer peripheral length, compared with a single core wire having a solid structure or a twisted wire formed by twisting together a plurality of metal wire strands having the same cross-sectional area. That is, the tubular conductor 21 has a larger area on the outer peripheral side, compared with a single core wire or a twisted wire. Accordingly, heat can be dissipated externally from a larger area, thus enabling heat dissipation to be improved.
(4) The conduction path 20 has the flexible conductors 23 and 24 connected to the tubular conductor 21. The flexible conductors 23 and 24 are superior in flexibility to the tubular conductor 21. Accordingly, dimensional tolerance of the conduction path 20 can be taken up. Also, when the vehicle V vibrates, positional shift between the components connected to either side of the flexible conductors 23 and 24 caused by this vibration can be absorbed. In the present embodiment, positional shift between the tubular conductor 21 and the connectors 71 and 72, that is, the tubular conductor 21 and the in-vehicle devices M1 and M2 can be absorbed. Accordingly, the load that is applied to the connectors 71 and 72 and terminals 25 and 26 can be reduced.
(5) The length L1 of the tubular conductor 21 is longer than the lengths L2 and L3 of the flexible conductors 23 and 24. Accordingly, the section where the cooling medium 43 that is circulated by the cooling tubes 41 and 42 contacts the tubular conductor 21 is long, that is, the section where heat exchange occurs between the cooling medium 43 and the tubular conductor 21 can be lengthened, thus enabling the conduction path 20 to be further cooled.
(6) The flexible conductors 23 and 24 are braided members formed by braiding metal wire strands into a tubular shape. The cooling tubes 41 and 42 can thus be respectively led out through the flexible conductors 23 and 24, partway along the flexible conductors 23 and 24. The cooling tubes 41 and 42 can thereby be easily led outside the wire harness unit 10, and the constituent members for circulating the cooling medium 43 can be easily connected to the tubular conductor 21.
(7) The electromagnetic shielding member 50 covers two conduction paths 20. The electromagnetic shielding member 50 is a braided member formed by braiding metal wire strands into a tubular shape. External emission of electromagnetic noise that is generated from the conduction paths 20 can thus be suppressed. Also, the cooling tubes 41 and 42 can thus be led out through the electromagnetic shielding member 50, partway along the electromagnetic shielding member 50. The cooling tubes 41 and 42 can thereby be easily led outside the wire harness unit 10, and the constituent members for circulating the cooling medium 43 can be easily connected to the tubular conductors 21.
(8) The wire harness unit 10 includes the exterior member 60 that covers the conduction paths 20 and at least part of the cooling tubes 41 and 42. The exterior member 60 has the tubular exterior member 61 and the grommets 62 and 63 respectively connected to the first end portion 61a and the second end portion 61b of the tubular exterior member 61. The cooling tubes 41 and 42 respectively pass through the grommets 62 and 63. In this way, the cooling tubes 41 and 42 respectively pass through the grommets 62 and 63 and are led outside the wire harness unit 10, thus enabling deterioration in the water sealing performance of the wire harness unit 10 to be suppressed.

### Example Modifications

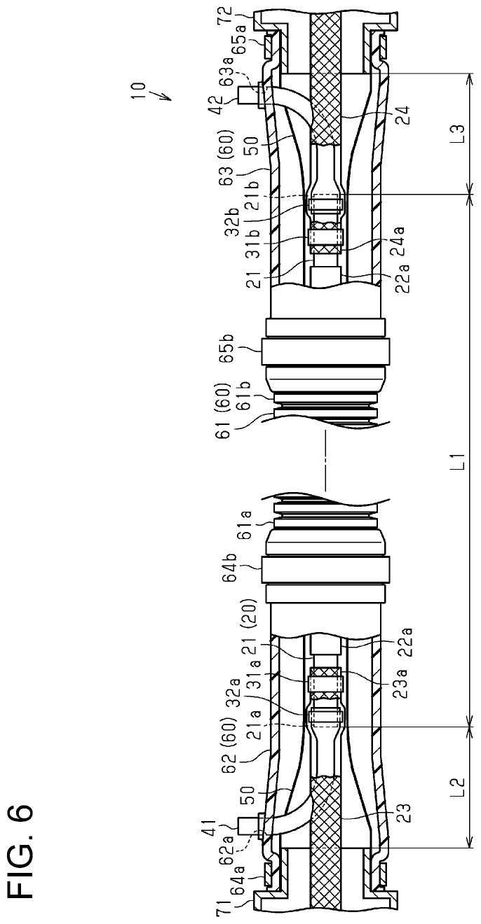

The present embodiment can be implemented in a modified manner as follows. The present embodiment and the following example modifications can be implemented in combination with each other to the extent that there are no technical inconsistencies.
As shown in FIG. 6, part of the cooling tubes 41 and 42 may be respectively covered by the flexible conductors 23 and 24. To elaborate, the first end portion 23a of the tubular flexible conductor 23 covers the first end portion 21a of the tubular conductor 21, the end portion of the cooling tube 41 connected to the first end portion 21a, and the fastening band 32a that crimps the cooling tube 41 to the tubular conductor 21. The cooling tube 41 is drawn outside the flexible conductor 23 through a gap between the braided wire strands constituting the flexible conductor 23. Similarly, the first end portion 24a of the tubular flexible conductor 24 covers the second end portion 21b of the tubular conductor 21, the end portion of the cooling tube 42 connected to the second end portion 21b, and the fastening band 32b that crimps the cooling tube 42 to the tubular conductor 21. The cooling tube 42 is drawn outside the flexible conductor 24 through a gap between the braided wire strands constituting the flexible conductor 24.
In the above embodiment, the two cooling tubes 41 may be connected to each other to supply the cooling medium 43 inside the respective tubular conductors 21. Also, the two cooling tubes 42 may be connected to each other to discharge the cooling medium 43 from inside the tubular conductors 21.

For example, on the supply side of the cooling medium 43 with respect to the wire harness unit 10, one cooling tube is connected to the cooling tubes 41 shown in FIG. 3, and the cooling medium 43 that is supplied from the one cooling tube is branched into the two cooling tubes 41. The branched portion of the cooling tube can be external to the grommet 62 or can be disposed inside the grommet 62. By adopting this configuration, one cooling tube need only be connected to the wire harness unit 10 in order to supply the cooling medium 43, and the attachment process to the wire harness unit 10 can be simplified.

Also, on the discharge side of the cooling medium 43 with respect to the wire harness unit 10, the two cooling tubes 42 are connected and the cooling media 43 in both cooling tubes 42 are merged. The merged portion of the cooling tubes can be external to the grommet 63 or can be disposed inside the grommet 63. By adopting this configuration, one cooling tube need only be connected to the wire harness unit 10 in order to discharge the cooling medium 43, and the attachment process to the wire harness unit 10 can be simplified.
In the above embodiment, the cooling tubes 41 and 42 are respectively led out through the grommets 62 and 63, that is, the cooling tubes 41 and 42 respectively pass through the grommets 62 and 63, but the cooling tubes 41 and 42 may be respectively led out through the connectors 71 and 72. By adopting this configuration, the tubular conductor 21 and the connectors 71 and 72 can be cooled.
The electromagnetic shielding member 50 of the above embodiment may be a metal tape or the like.
In the above embodiment, a wire harness unit including one or three or more conduction paths may be provided.
As the flexible conductors 23 and 24 of the above embodiment, a twisted wire formed by twisting together a plurality of metal wire strands may be used.
In the above embodiment, the tubular flexible conductors 23 and 24 may not cover the tubular conductor 21. For example, the flexible conductors 23 and 24 may be electrically connected to the tubular conductor 21, by forming the tubular flexible conductors 23 and 24 into a round rod shape, and respectively crimping the flexible conductors 23 and 24 to the outer peripheral surface of the tubular conductor 21 with the fastening bands 31a and 31b. In this case, the first end portion 21a and the second end portion 21b of the tubular conductor 21 need not be led out from between the wire strands of the flexible conductors 23 and 24, enabling assembly to facilitated.
In the above embodiment, the tubular flexible conductors 23 and 24, for example, may be sheet shaped, and these flexible conductors 23 and 24 may be wrapped in a sushi roll shape around the outer peripheral surface of the tubular conductor 21, and respectively crimped to the tubular conductor 21 by the fastening bands 31a and 31b. The flexible conductors 23 and 24 may be respectively wrapped around cooling tubes 41 and 42 that pass through the tubular conductor 21, or may not be wrapped therearound. In the case where the flexible conductors 23 and 24 are respectively wrapped around the cooling tubes 41 and 42, the cooling tubes 41 and 42 can be easily drawn out from between the flexible conductors 23 and 24 that overlap the cooling tubes 41 and 42 in a sushi roll shape.
In the above embodiment and example modifications, the shape of the flexible conductor 23 on the connector 71 side and the shape of the flexible conductor 24 on the connector 72 side are the same as each other, but may differ from each other. For example, the first end portion 21a of the tubular conductor 21 may be arranged on the inner side of a tubular flexible conductor 23 and the flexible conductor 23 and the tubular conductor 21 may be connected to each other by the fastening band 31a, and a rod-shaped flexible conductor 24 may be crimped to the outer peripheral surface of the tubular conductor 21 by the fastening band 31b to connect the flexible conductor 24 and the tubular conductor 21 to each other.
In the above embodiment, the cooling medium 43 may be supplied inside the tubular conductor 21 from the cooling tube 42, and the cooling medium 43 may be discharged from inside the tubular conductor 21 by the cooling tube 41.
The tubular conductor 21 can have a lengthwise shape that depends on the routing path of the wire harness unit 10. The rigidity of the tubular conductor 21 may be such that the lengthwise shape and/or widthwise shape of the tubular conductor 21 does not change immediately before or immediately after installing the wire harness unit 10 in a vehicle.
As shown in FIG. 3, the wire harness unit 10 according to certain preferred examples can includes the tubular conductor 21, the plurality of cooling tubes 41 and 42, the plurality of flexible conductors 23 and 24, and the electromagnetic shielding member 50. The tubular conductor 21 may have a pipe internal space and two pipe opening ends. Each of the cooling tubes 41 and 42 may have a tube internal space and two tube end portions. First tube end portions of the cooling tubes 41 and 42 may be respectively connected to the two pipe opening ends of the tubular conductor 21, such that the pipe internal space of the tubular conductor 21 and the tube internal spaces of the plurality of cooling tubes 41 and 42 communicate and form a refrigerant circuit. Second tube end portions of the cooling tubes 41 and 42 may each extend radially outward from the electromagnetic shielding member 50 via gaps between loosened metal wire strands in the electromagnetic shielding member 50. The plurality of flexible conductors 23 and 24 may be electrically connected to the outer peripheral surface of the tubular conductor 21, in respective vicinities of the two pipe opening ends of the tubular conductor 21 on the inner side of the electromagnetic shielding member 50.
As shown in FIG. 4, in the wire harness unit 10 according to certain preferred examples, the inner peripheral surface 21d of the tubular conductor 21 may be covered by the protective layer 22b that extends over the entire length of the tubular conductor 21. The protective layer 22b may be terminated at both opening ends of the tubular conductor 21, and the protective layer 22b need not extend outward in the length direction from either opening end of the tubular conductor 21. The protective layer 22b may be a coating extending over the entire length of the tubular conductor 21 or a surface treated layer that may be referred to as a lining or a coating.

1. A wire harness unit comprising:
a conduction path that conducts electricity between in-vehicle devices; and
a cooling tube that cools the conduction path, wherein:
the conduction path has a hollow tubular conductor having conductivity,
the cooling tube is more flexible than the tubular conductor and is separate from the tubular conductor,
the cooling tube is connected to an end of the tubular conductor, and
the tubular conductor and the cooling tube are configured to circulate a cooling medium therethrough.

2. The wire harness unit according to claim 1, comprising:
a protective layer covering an inner peripheral surface of the tubular conductor.

3. The wire harness unit according to claim 1, wherein:
the conduction path has a flexible conductor and a terminal,
the flexible conductor has a first end electrically connected to the tubular conductor and a second end electrically connected to the terminal, and
the flexible conductor is more flexible than the tubular conductor.

4. The wire harness unit according to claim 3,
wherein the tubular conductor is longer than the flexible conductor.

5. The wire harness unit according to claim 1, comprising:
an electromagnetic shield covering the tubular conductor and at least part of the cooling tube, wherein:
the electromagnetic shield is a braided member formed by braiding metal wire strands, and
the cooling tube passes through the braided member.

6. The wire harness unit according to claim 1, comprising:
an exterior cover that covers the conduction path and at least part of the cooling tube, wherein:
the exterior cover has a tubular exterior and a grommet connected to an end of the tubular exterior, and
the cooling tube passes through the grommet.
